(19) United States
(12) Patent Application Publication
(10) Pub. No.: US 2021/0178928 A1
(43) Pub. Date: Jun. 17, 2021

(54) SERVICE LIFE CONTROL FOR ENERGY STORES

(71) Applicant: Siemens Aktiengesellschaft, 80333 München (DE)

(72) Inventors: Swen RUPPERT, Möhrendorf (DE); Eugen HOLL, Langenzenn (DE)

(73) Assignee: Siemens Aktiengesellschaft, 80333 München (DE)

(21) Appl. No.: 16/076,270

(22) PCT Filed: Jan. 26, 2017
(86) PCT No.: PCT/EP2017/051648

§ 371 Date: Aug. 7, 2018

(30) Foreign Application Priority Data
Feb. 8, 2016 (EP) 16154678.3

(51) Int. Cl. B60L 58/13; B60L 58/16; B60L 58/26; B60W 20/20

(52) U.S. Cl. CPC B60L 58/13; B60W 20/20; B60L 58/26; B60L 58/16

(57) ABSTRACT

In a method for controlling the service life of an energy storage module, a state of health (SoH) of the energy storage module is known at different times. In order to improve the control of the service life of an energy storage module, it is proposed that a speed of ageing is determined from a first known state of health of the energy storage module at a first time, and a second state of health of the energy storage module at a second time, wherein an end time of a determined end of service life is calculated from the speed of ageing and from one of the known states of health (SoH), wherein depending on the calculated end time of the determined end of service life a measure for changing the service life of the energy storage module is applied.

The invention relates to a method for controlling the service life of an energy storage module, wherein a state of health of the energy storage module is known at different times. The invention also relates to a method for controlling the service life of a multiplicity of energy storage modules. In addition, the invention relates to a control system for an energy storage module and to an energy storage module and to an energy storage system comprising said control system. The invention also relates to a vehicle comprising said energy storage module.

An energy storage device can be constructed from one or more energy storage modules. The energy storage module usually comprises sensors for determining the temperature of the energy storage module. In addition, the energy storage module is often assigned a closed-loop or open-loop control unit, which can be used to influence the behavior and operation of the energy storage module.

Today, double-layer capacitors (known as supercaps or ultracaps) or batteries are used by preference as an energy storage device or energy storage module in particular in a drive system for vehicles.

It is known that operating conditions of, and external influences on, an energy storage device or an energy storage module determine the limits of the energy storage device and determine the cooling. For instance, the current limits are reduced in the event of overheating, recharging is restricted according to the state of charge (SoC), or in a hybrid system, another power or energy source is connected to the system when the SoC is low. In addition, the cooling can be increased.

DE 10 2013 213 253 A1 discloses that changing the operating parameters can have an influence on the efficiencies of energy storage systems.

Temperature and voltage sometimes have a major impact on the service life of electrical energy storage devices (double-layer capacitors, ultracaps and batteries). The current, on the other hand, has an effect on the temperature via heating.

If leasing agreements or warranties make it desirable to guarantee a defined service life of the energy storage system, it is present practice to make a conservative design that includes safeguards on the service life and to add a tolerance to the design. This tolerance buffer is associated with additional complexity and hence with costs or losses, for instance over-dimensioning, restricting the operating parameters (e.g. the maximum voltage) or a high installed cooling capacity.

The state of health, also known as the age of an energy storage system, is often derived from the capacitance or other parameters such as internal resistance, for instance. For this purpose, algorithms are known for determining the state of health of the energy storage module. The state of health is often abbreviated to SoH. 100% is considered here to be the as-new value. The critical state of health, at which the energy storage device should be taken out of service for safety reasons or to ensure trouble-free operation, is typically reached at about 80%. Other definitions define the critical state of health at 0%. Irrespective of the definition of the state of health (SoH), at the critical state of health there is always still the capability of storing or releasing energy.

The guaranteed service life of an energy storage system is usually designed for the system (e.g. vehicle) in which the energy storage device is meant to buffer energy. It is often the case here that the service life of the system is equal to, or twice as high as, the calculated service life of the energy storage system.

EP 2 481 123 B1 discloses a method for open-loop and/or closed-loop control of at least one operating parameter of the electrical energy storage device, which operating parameter influences the state of health of an electrical energy storage device, comprising the steps of determining the actual state of health of the electrical energy storage device, comparing the actual state of health with a target state of health specified for the present age of the energy storage device, and restricting an operating parameter range permitted for the at least one operating parameter if the actual state of health is worse than the target state of health.

The object of the invention is to improve the open-loop or closed-loop control of the service life of an energy storage module.

The object is achieved by a method for controlling the service life of an energy storage module, wherein a state of health of the energy storage module is known at different times, wherein a first state of health, in which the energy storage module finds itself at a first time, is known, and a second state of health, in which the energy storage module finds itself at a second time, is known, wherein an ageing rate is determined from the first and second states of health and from the first and second times, wherein a time of a determined end of service life is calculated from the ageing rate and one of the states of health, wherein depending on the time of the determined end of service life, a measure for changing the service life of the energy storage module is applied. The object is also achieved by a method for controlling the service life of a multiplicity of energy storage modules, wherein closed-loop control of at least a first energy storage module of the multiplicity of energy storage modules having a first time of the determined end of service life is performed by an aforementioned method such that the first time of the determined end of service life approximates a definable time. The object is also achieved by a control system for an energy storage module comprising means for performing a method of this type, and by a program for performing a method of this type on being executed in said control system, and by a computer program product. In addition, the object is achieved by an energy storage module comprising said control system, an energy storage system comprising a multiplicity of energy storage modules, and by a vehicle comprising said energy storage module.

The dependent claims define advantageous embodiments of the invention.

The invention is based on the finding that an expected end of service life of the energy storage module can be calculated from the states of health (SoH) at different times. For the calculation, the state of health (SoH) must be known at at least two different times. If the difference in the two states of health (the first state of health and the second state of health) is formed, and this is divided by the difference in the two times, then an ageing rate is obtained from these two states of health. Using the calculated ageing rate, the end of service life can be determined from a state of health and the associated time. This process can use one of the states of health, i.e. the first or second state of health, that was already used to calculate the ageing rate, or any other known state of health with the associated time. The state of health at a specific time can be used to calculate when a defined state of health, which defines the end of the energy storage module, is reached. This is done easily by assuming in the calculation that the ageing continues to proceed at the calculated ageing rate.

Based on this time for reaching the end of service life, a decision can be made regarding whether an open-loop or closed-loop control system takes measures to change the service life.

The method described above involves linearization through two points. Specifically, determining the ageing rate involves placing a straight line through these two points and calculating an intersection when this straight line reaches a defined state of health, i.e. intersects a value parallel to the time axis, at which value the energy storage module must be replaced. This intersection constitutes the calculated time of the end of service life.

Alternatively, there are a large number of techniques, in particular statistical techniques, known from mathematics for determining or interpolating a straight line or line of best fit from a set of points or measurement points in a two-dimensional space. All these techniques are suitable for determining the ageing rate of an energy storage module.

One advantage of the method for service-life control is that it is possible to prevent unexpected ageing shortly before the scheduled replacement of the energy storage module, i.e. shortly before its end of service life. The predictive nature of the method for service-life control allows the service life of the energy storage module to be controlled, in particular extended, and also facilitates an operation of the energy storage module that prevents, or at least makes unlikely, a failure shortly before the scheduled end of service life.

A recovery effect of the SoH value is observable in many energy storage devices. This is masked by the method used here if the period under consideration, and hence the states of health that lie in the period under consideration, are suitably chosen for determining the ageing rate. It has proved useful in this case to perform the calculation of the ageing rate only once an initial early phase of the energy storage device operation, in which the recovery effect is active, has passed. During the recovery phase, ageing of the energy storage module does not proceed linearly and hence deviates, sometimes even significantly, from a calculated, constant ageing rate. A calculation of the time of the end of service life on the basis thereof is therefore prone to errors and sometimes very inaccurate, It has hence proved advantageous not to use the first measured values of the state of health after start of operation of the energy storage module for calculating the ageing rate. The determined states of health are used for determining the ageing rate only once the energy storage module has been operating for some time, for instance one minute, ten minutes or an hour, depending on the application. Alternatively, the first states of health can be given a weighting factor, so that they have a lower impact on the calculation of the ageing rate, in particular when the calculation uses statistical techniques from mathematics. The time of the end of service life can hence be calculated more accurately.

In an advantageous embodiment of the invention, depending on the size of the time interval between a time of a scheduled end of service life and the time of the determined end of service life, a measure for changing the service life of the energy storage module is applied. This provides the closed-loop or open-loop control system with a criterion for selecting when it is appropriate, or may be appropriate, to initiate measures for the energy storage module that extend the service life. For this purpose, for example in advance during the design of the energy storage module, the variation over time of the state of health is calculated or simulated as a function of time under certain design conditions or ambient conditions and conditions of use or usage scenarios. The time of the scheduled end of service life can also be determined by means of this variation over time. The simulation can be performed here by computation or on the basis of trials, and in combination. The variation of the state of health over time is not necessarily linear. It has been found that especially in an early period, the variation is not linear and only changes into a linear variation from a certain time onwards. The calculation or simulation yields, inter alia, this time, from which point onwards the ageing, i.e. the change in the ageing rate, proceeds practically linearly. It is only from this time onwards that the method is particularly advantageous because of the accuracy it then has. In addition, it is also possible to correct for the recovery effect, which normally would result in calculating a time of the end of service life that is too early. Hence calculating the time of the determined end of service life by means of the ageing rate provides a far more accurate result than methods known hitherto for controlling the service life of an energy storage module.

It has proved advantageous here that the performance of an energy storage module can be increased easily by shifting the time of the scheduled end of service life to an earlier time. This allows heavier loading of the energy storage module, for instance by higher currents, by a higher number of cycles, or a higher ambient temperature. It is hence easily possible in many cases, even after delivery of a system or a vehicle, to implement an additional or new customer requirement for increased performance by simply adjusting a parameter, for instance the value of the time of the scheduled end of service life. This adjustment involves setting the value of the time of the scheduled end of service to an earlier time.

The information on the time of the determined end of service life can be used in order to be able to schedule more accurately servicing measures for the system or vehicle, because these are known sufficiently accurately and in sufficient time. This simplifies the logistics of scheduling the vehicle use and organizing the servicing, from implementation through to spare-parts procurement.

In another advantageous embodiment of the invention, for the case in which the time of the determined end of service life lies before the time of the scheduled end of service life, a measure for changing the service life is applied, wherein the measure for changing the service life is a measure for extending the service life. A particularly advantageous energy storage module can be produced if the design does not include over-dimensioning or reserves. At the same time, however, to prevent a failure or the end of service life being reached before the scheduled end of service life given a high run-down of service life, i.e. when an ageing rate is high, identifiable from an early time of the determined end of service life, the closed-loop or open-loop control system of the energy storage module can initiate measures for extending the service life, In this case, an extension of the operation of the energy storage module can be achieved with only slight restrictions on the operation. It has been found that during operation of the vehicle or system, the energy storage module is utilized or loaded far less heavily than stipulated. These design reserves can be used to extend the service life. In this case, controlling the service life often still does not result in restrictions on the operation or in a reduction in the efficiency of the system.

In another advantageous embodiment of the invention, depending on at least one operating parameter of the energy storage module and/or at least one ambient condition, with the aid of data stored in a memory, open-loop or closed-loop control of the operation of the energy storage module is performed such that in order to change the service life of the energy storage module, a cooling capacity of the energy storage module is changed and/or an operating strategy of the energy storage module is altered and/or an operating variable of the energy storage module is limited. It has been found that for changing the service life of the energy storage device it is advantageous to implement the measures mentioned depending on one or more operating parameters or one or more ambient conditions. It has proved advantageous here for selecting suitable measures, to store in a data memory (lookup table) a decision criterion such as, for instance, a change in the efficiency, and to use said criterion for deciding the measure rather than calculating online the effect of the measure. By virtue of the storage, a good response when introducing measures that extend the service life can be achieved without a large amount of computing power.

The measures can be classified into the groups mentioned above. For the increase in cooling capacity, for instance, the flow rate of the cooling medium or coolant can be increased. This is achieved easily for air cooling by increasing the fan speed, or for liquid cooling by increasing the pump delivery rate. Additionally or alternatively, there is also the option to reduce the temperature of the coolant. For instance, for air cooling this can be done by an air conditioning unit, which can lower the temperature of the cooling air, or for liquid cooling by increasing the performance of a heat exchanger which dissipates the heat contained in the cooling fluid to the surrounding air.

Altering the operating strategy relates to aspects which cause loading of the energy storage module but which cannot necessarily be measured directly from electrical variables using a sensor. These aspects include, for example, reducing the acceleration of the vehicle. Equally possible is to reduce the number of cycles that result for the energy storage device from charging and discharging. Reducing this cycle count is achieved, for example, by discharging an energy storage module only once it has reached a certain specifiable minimum state of charge.

The limiting of operating variables relates to the variables, in particular electrical variables, that can be measured by a sensor. These include in particular the current through the energy storage module. Since the current has a direct effect on the temperature and thus also on the service life of the energy storage device, this measure is particularly effective. It also involves a large constraint on the operation of the energy storage module, however.

In another advantageous embodiment of the invention, the cooling capacity of the energy storage module is increased if a temperature measured in the energy storage module is greater than an averaged or smoothed value of the temperature stored in the energy storage module and/or if a measured ambient temperature is greater than an averaged or smoothed value of the measured ambient temperature. It has proved beneficial if the cooling capacity is increased when the temperature of the energy storage module and/or ambient temperature is high. A high temperature both in the energy storage module and in the ambient area can be identified if this temperature lies above its averaged or smoothed value. In this case, the cooling capacity can be increased immediately on this averaged or smoothed value being exceeded, or when the averaged or smoothed value is exceeded by a definable amount.

The averaged value is calculated by forming over a defined time window the mean value of these values. Usually smoothing can be implemented more easily than averaging within the closed-loop control system. This smoothing involves smoothing the temperature signal, for instance in a simple manner by means of a PT1 element. The memory required is far smaller than for averaging.

A particular advantage of this embodiment is that the cooling is increased especially in particular at the times when there is a high temperature and hence high loading. The service life of the energy storage module can hence be extended by a simple measure that causes practically no impairment, or no impairment at all, of the operation of the system or vehicle.

In another advantageous embodiment of the invention, the cooling capacity is increased according to the difference between the temperature measured in the energy storage module and the measured ambient temperature. It is especially when there is a large difference between the temperature measured in the energy storage module and the ambient temperature that the increase in the cooling capacity counters the loss in service life that then exists. Owing to the high temperature difference, increasing the cooling capacity is particularly effective if the coolant flow rate is increased. It has proved particularly advantageous in this case if the cooling capacity is increased linearly with, or as the square of, the temperature difference between the temperature measured in the energy storage module and the measured ambient temperature.

In another advantageous embodiment of the invention, the operating strategy of the energy storage device is altered in the manner that the maximum state of charge is lowered and/or the minimum depth of discharge is increased. The loading of an energy storage module is relatively high especially at its limits of the state of charge. At maximum charge, in particular when using double-layer capacitors, the voltage, in particular the voltage of the individual capacitors cells, is quite high and hence constitutes loading, i.e. increased ageing, for the energy storage module. At minimum charge, the voltage falls, and in order to exchange a certain amount of energy, a higher current is needed, which results in more heating and hence to higher loading of the energy storage module. By reducing the amount of energy that can be stored in the energy storage module by raising the minimum depth of discharge (DoD) and/or lowering the maximum state of charge (SoC), the loading of the energy storage module can be reduced easily, and the service life increased. This type of measure is an example of altering the operating strategy.

In another advantageous embodiment of the invention, the operating strategy of the energy storage module is altered in the manner that the number of cycles is reduced. In order to increase the service life of an energy storage module, it has proved advantageous to reduce the number of cycles, i.e. the sequence of charging and discharging operations. This can be done easily, in the case of charging the energy storage module, by not discharging this module again until the energy storage module has stored a certain minimum amount of electrical energy. The energy storage device is only discharged again once this value is reached. This prevents charging cycles that achieve only a small energy exchange, i.e. have only a small energy displacement, yet still have a sometimes significantly negative effect on the service life of the energy storage module. Nonetheless, the vehicle or system can still always bring into the energy storage module recovered energy, e.g. during a braking operation, and store the energy in an environmentally friendly manner. Hence it is only the provision of energy by the energy storage module that is prevented at certain times, such as in an acceleration operation for instance. Thus the energy storage device can receive excess energy from the drive, and therefore its positive environmental credentials remain intact, because excess energy does not need to be converted into heat or eliminated.

In another advantageous embodiment, the current flowing through the energy storage module is limited. This current causes heating inside the energy storage device as a result of its Ohmic losses in the energy storage device. This heating has a negative impact on the service life of the energy storage device. The warmer the energy storage module, the greater is this impact. Thus by limiting the current flowing through the energy storage module, it is easy to reduce heating, and hence loading, of the energy storage device which leads to a reduction of the service life.

In another advantageous embodiment of the invention, the discharge current from the energy storage module is limited. If just the discharge current is limited, and there is no limit placed on the charging current, the energy storage module can continue energy. It is hence possible to ensure that no electrical energy is converted into heat, for instance via a braking resistor, but is available for reuse in the drive. Hence the efficiency of the system or vehicle, in particular of the drive of the vehicle, continues to remain high even with this measure for increasing the service life. Despite the action of this measure for extending the service life, the energy storage module continues to be environmentally friendly because no energy needs to be converted into heat. Thus increased energy consumption or even energy wastage is ruled out despite the action of the measures for extending the service life. The efficiency of the complete system is thus practically as high as ever. Only the performance, for example during acceleration of a vehicle, is restricted by this measure but without any significant impairment of the overall efficiency of the system.

The invention is described and explained in greater detail below with reference to the exemplary embodiments shown in the figures, in which:

FIG. 1 shows a block diagram of a closed-loop control system;

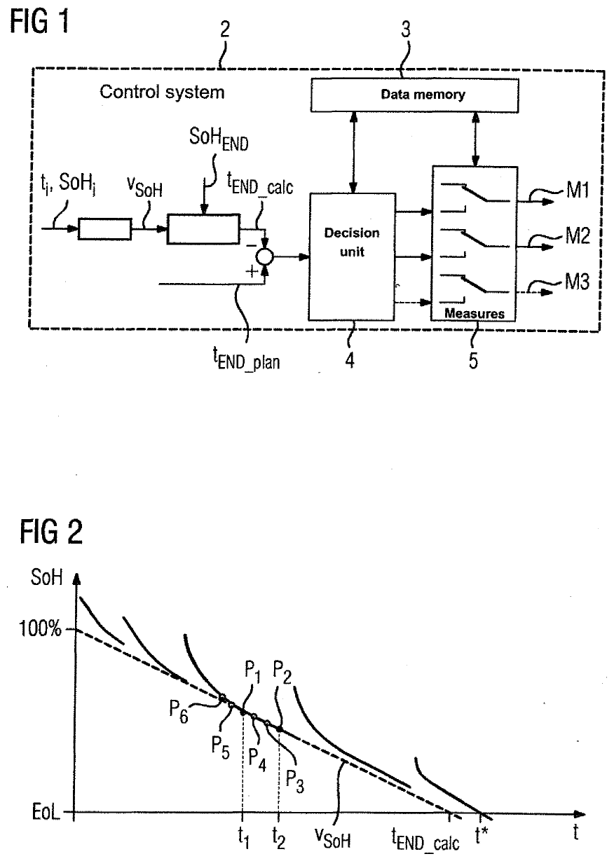

FIG. 2 shows the variation in the state of health over time;

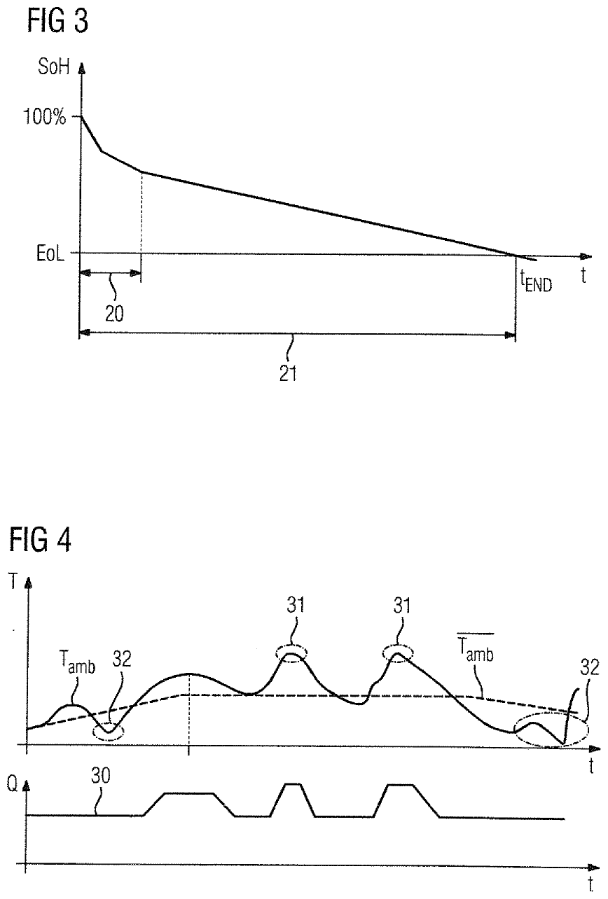

FIG. 3 shows calculating the scheduled end of service life;

FIG. 4 shows a first measure for increasing the service life;

FIG. 5 shows a further measure for increasing the service life; and

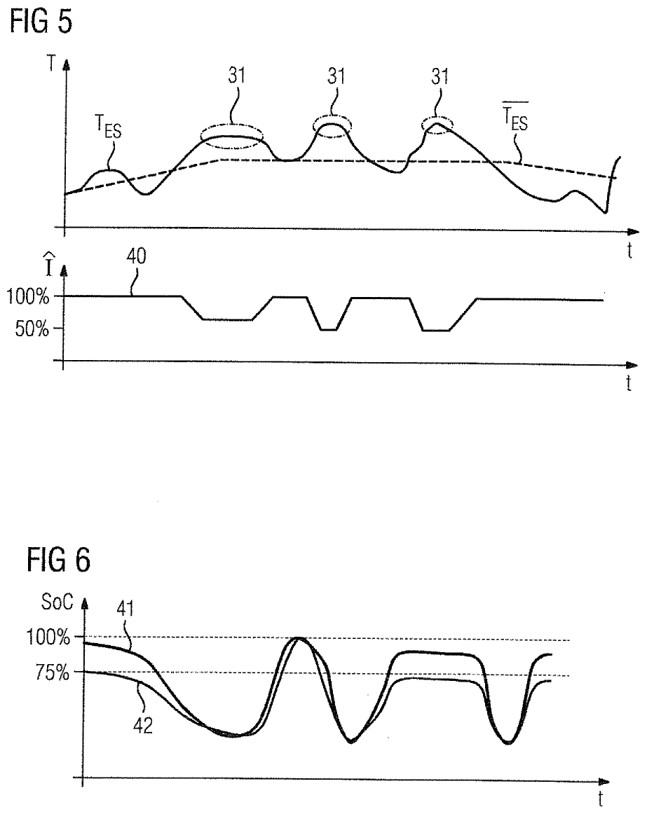

FIG. 6 shows reducing the maximum state of charge,

FIG. 1 shows the block diagram of a control system for controlling the service life of an energy storage module 1, which is not shown here. The signals relating to the state of health SoHᵢ of the energy storage module 1 at different times tᵢ serve as the input variables to this closed-loop controller, The individual states of health SoHᵢ can be determined, for example, via the internal resistance or the capacitance of the energy storage module 1. The ageing rate V_{SoH} can be determined from at least two of the states of health SoHᵢ and the associated times tᵢ. It is obtained, for example, by dividing the difference in the two states of health SoHᵢ by the difference in the associated times tᵢ. Additional states of health SoHᵢ can be used to improve the determination of the ageing rate, for instance in terms of accuracy. Apart from calculating the ageing rate V_{SoH} by means of the difference in two states of health SoHᵢ, it has also proved useful to determine the ageing rate V_{SoH} using statistical techniques such as by means of median values, for instance. In this case, the multiplicity of the states of health SoHᵢ involved in the determination improves the determination of the ageing rate V_{SoH}. The time t_{END_calc} of the determined end of service life can be determined from the ageing rate V_{SoH} if a state of health SoH_{END} at which the energy storage module is meant to be replaced, i.e. the end of its service life (EoL, End of Life), is specified for the calculation. From a comparison between the determined end of service life t_{END_calc} and a scheduled end of service life t_{END_plan} it is possible to decide whether measures for influencing the service life are applied. This has proved advantageous especially when the scheduled end of service life t_{END_plan} is later than, i.e. is after, the determined end of service life t_{END_calc}.

The difference between the time t_{END_calc} of the determined end of service life and a time t_{END_plan} of a scheduled end of service life is passed to a decision unit 4 as a control error. In order for this decision unit 4 to influence the service life of the energy storage module 1, previously stored data from a data memory 3 is used to select a suitable measure M1, M2, M3 for changing the service life. In this process, for instance, the operating status of the energy storage module or of the system or of the vehicle can be used in order to select from the available measures M1, M2, M3 one or more measures having a minimum possible impact on the operation. The measures M1, M2, M3 are therefore preferably selected on the basis of the control error via a database (energy loss calculation, lookup table), which was determined offline. The database is stored in the data memory 3 and ensures that there is little impact on, or little reduction in, the overall efficiency of the system. It has also proved advantageous to get the measures M1, M2, M3 to have an effect when they have the most impact on changing, in particular extending, the service life, while at the same time being associated with minimum energy loss. This decision criterion can also be stored in the data memory. The individual measure Mᵢ or even the plurality of measures M1, M2, M3 are initiated here by the means 5 for implementing measures.

FIG. 2 shows an example of determining the ageing rate V_{SoH}, i.e. determining the gradient in the variation of the state of health SoH over time t. In this exemplary embodiment, the states of health SoHᵢ at the points P₁ and P₂ are used for this purpose. A straight line is determined therefrom, the gradient of which equals the ageing rate v_{SoH}. In this example, the state of health SoH does not proceed linearly over time t. Instead, the state of health SoH fluctuates, with there being repeated phases of recovery of the energy storage module 1 at which the state of health assumes a higher value. These phases occur, for example, during breaks in operation, in particular prolonged breaks in operation. These phases are also known as the recovery effect. For calculating the ageing rate v_{SoH}, it is advantageous to use points Pᵢ at which the recovery effect has already decayed away. It is also advantageous to select the interval for determining the ageing rate V_{SoH} to be neither too large nor too small, so that the calculation result is not on measurement tolerances.

The time T_{END_calc} of the end of the determined service life is found from the intersection of the straight lines with the axis EoL of the end of service life. This may differ from the actual time t* for the end of service life, for instance because of measurement errors.

FIG. 3 shows a typical variation of the state of health SoH of an energy storage module 1 over time t. This can be determined for an energy storage module 1 both by means of computation and from trials. The service life 21 encompasses here the time span from the start of operation of the energy storage module 1, at which it has a state of health of 100%, up to the time t_{END} of the end of service life. At the start of operation, this characteristic curve has a non-linear region 20. It has proved advantageous to use measured values of the state of health SoH only outside the non-linear region 20 for determining the ageing rate V_{SoH}, because measured values within the non-linear region 20 would result in calculating an end of service life that is too early.

FIG. 4 shows as an example of a measure for extending the service life of the energy storage module 1 the variation over time of the ambient temperature T_{amb} and the variation 30 over time of the coolant flow rate Q. In this example, it proved advantageous to increase the coolant flow rate Q in regions 31 of high temperature T. For example, temperature values T that lie above an averaged or smoothed ambient temperature T̅_̅{̅a̅m̅b̅}̅, or which exceed the averaged or smoothed value of the ambient temperature T̅_̅{̅a̅m̅b̅}̅ by a defined value or a defined factor, are considered to be regions 31 of high temperature. It has proved advantageous here to increase the coolant flow rate Q according to the difference between the ambient temperature and the averaged or smoothed ambient temperature T̅_̅{̅a̅m̅b̅}̅.

In addition, in regions 32 of low ambient temperature, for instance such as in the winter or overnight, the cooling capacity can be reduced. A reduction in the cooling capacity is not shown in FIG. 4 for reasons of clarity.

The increase in the coolant flow rate Q can be achieved, for instance, for air cooling by increasing a fan speed. For liquid or water cooling, the coolant flow rate Q can be increased, for example, by increasing the pump delivery rate.

As an alternative to the ambient temperature T_{amb}, it is also possible to use the temperature T_{ES} of the energy storage device and/or a temperature inside the energy storage device for the open-loop or closed-loop control of the coolant flow rate Q.

FIG. 5 shows reducing the maximum current value Î according to the temperature in the energy storage device T_{ES}, The variation 40 of the maximum current value Î is shown for this purpose. In the region of 31 of high temperatures T, the maximum current value Î of the current I through the energy storage module 1 is reduced. In particular, times at which the temperature in the energy storage device T_{ES} exceeds, or exceeds by a defined value or factor, the averaged or smoothed value of this temperature T̅_̅{̅a̅m̅b̅}̅ are regarded as regions 31 of high temperatures T. In this case, the level of the reduction can be made dependent on the difference between the temperature in the energy storage device T_{ES} and the averaged or smoothed value of this temperature T̅_̅{̅a̅m̅b̅}̅.

An alternative measure for influencing the service life of the energy storage module 1 involves limiting the state of charge SoC of the energy storage device. For this purpose, the maximum state of charge SoCₘₐₓ can be lowered from a value of 100% to a reduced value of, for instance, 75%. FIG. 6 shows in this connection the first variation 41 over time of a state of charge SoC, which is not subject to any limitation on the maximum state of charge SOCₘₐₓ (i.e. SoCₘₐₓ=100%), and a second variation 42 over time of a state of charge SoC, which is subject to a limitation on the maximum state of charge SoCₘₐₓ (for example SoCₘₐₓ=75%). It has proved advantageous here to allow, even in the case of the limitation on the maximum state of charge SOCₘₐₓ, briefly a state of charge that exceeds the maximum state of charge SoCₘₐₓ, because exceeding only briefly has only a negligible impact on the service life of the energy storage module 1 while maintaining a high efficiency of the energy storage system.

To summarize, the invention relates to a method for controlling the service life of an energy storage module, wherein a state of health of the energy storage module is known at different times. in order to improve the control of the service life of an energy storage module, it is proposed that the ageing rate is determined from a first state of health, in which the energy storage module find itself at a first time, and from a second state of health, in which the energy storage module finds itself at a second time, wherein a time of a determined end of service life is calculated from the ageing rate and one of the states of health, wherein depending on the time of the determined end of service life, a measure for changing the service life of the energy storage module is applied.

1.-19. (canceled)

20. A method for controlling a service life of an energy storage module comprising double-layer capacitors, the method comprising:
determining varies states of health (SoH) of the energy storage module at a plurality of different times,
selecting from the determined states of health a first state of health at a first time, and a second state of health at a second time,
determining from the first and second states of health and from the first and second times an ageing rate of the energy storage module,
calculating from the ageing rate and one of the determined states of health an end time of the service life, and
depending on the calculated end time, increasing a cooling capacity of the energy storage module when a module temperature measured in the energy storage module is greater than an averaged or smoothed value of the temperature measured in the energy storage module or when a measured ambient temperature is greater than an averaged or smoothed value of the measured ambient temperature.

21. The method of claim 20, further comprising applying a measure for changing the service life of the energy storage module depending on a size of a time interval between an end time of a scheduled end of service life and the end time of the calculated end of service life.

22. The method of claim 21, wherein the measure for changing the service comprises a measure for extending the service life when the end time of the calculated end of service life precedes the end time of the scheduled end of service life.

23. The method of claims 20, further comprising:
depending on at least one operating parameter of the energy storage module or at least one ambient condition, or both, changing the service life of the energy storage module by controlling operation of the energy storage module by open-loop or closed-loop control using data stored in a memory by at least one of
changing the cooling capacity of the energy storage module,
changing an operating strategy of the energy storage module, and
limiting an operating variable of the energy storage module.

24. The method of claim 20, wherein the cooling capacity is increased according to a difference between the measured module temperature and the measured ambient temperature.

25. The method of claim 23, wherein the operating strategy of the energy storage module is changed by lowering a maximum state of charge or increasing a minimum depth of discharge.

26. The method of claim 23, wherein the operating strategy of the energy storage module is changed by reducing the number of charge and discharge cycles.

27. The method of claims 23, wherein the operating variable of the energy storage is changed by limiting a current flowing through the energy storage module.

28. The method of claim 27, wherein the current flowing through the energy storage module is a discharge current of the energy storage module.

29. The method of claim 20, wherein a plurality of energy storage modules are employed, the method comprising:
controlling operation of at least a first energy storage module of the plurality of energy storage modules having a first end time by open-loop or closed-loop control such that the first end time of the calculated end of service life approaches a predefined time.

30. The method of claim 29, further comprising:
when the first end time of the calculated end of service life precedes a second end time of the calculated end of service life of a second energy storage module, controlling the first energy storage so as to extend the service life of the first energy storage module.

31. The method of claim 29, wherein individual energy storage modules are controlled such that the respective end times of the calculated end of service life of the individual energy storage modules approach one another.

32. A control system for an energy storage module comprising double-layer capacitors, wherein the control system is configured to control a service life of the energy storage module by:
determining varies states of health (SoH) of the energy storage module at a plurality of different times,
selecting from the determined states of health a first state of health at a first time, and a second state of health at a second time,
determining from the first and second states of health and from the first and second times an ageing rate of the energy storage module,
calculating from the ageing rate and one of the determined states of health an end time of the service life, and
depending on the calculated end time, increasing a cooling capacity of the energy storage module when a module temperature measured in the energy storage module is greater than an averaged or smoothed value of the temperature measured in the energy storage module or when a measured ambient temperature is greater than an averaged or smoothed value of the measured ambient temperature.

33. A computer program embodied on a non-transitory storage medium an comprising program steps for controlling a service life of an energy storage module comprising double-layer capacitors, wherein the computer program when loaded into a memory of a control system and executed by the control system, causes the control system to
determine varies states of health (SoH) of the energy storage module at a plurality of different times,
select from the determined states of health a first state of health at a first time, and a second state of health at a second time,
determine from the first and second states of health and from the first and second times an ageing rate of the energy storage module,
calculate from the ageing rate and one of the determined states of health an end time of the service life, and
depending on the calculated end time, increase a cooling capacity of the energy storage module when a module temperature measured in the energy storage module is greater than an averaged or smoothed value of the temperature measured in the energy storage module or when a measured ambient temperature is greater than an averaged or smoothed value of the measured ambient temperature.

34. A computer program product comprising the computer program of claim 33.

35. An energy storage system comprising one or more energy storage modules having double-layer capacitors and at least one control system according to claim 32.

36. A vehicle, comprising the energy storage system of claim 35.

37. The vehicle of claim 36, wherein the vehicle comprises a rail vehicle or an aircraft.
